(19) United States
(12) Patent Application Publication
(10) Pub. No.: US 2013/0001550 A1
(43) Pub. Date: Jan. 3, 2013

(54) HERMETICALLY SEALED MEMS DEVICE WITH A PORTION EXPOSED TO THE ENVIRONMENT WITH VERTICALLY INTEGRATED ELECTRONICS

(75) Inventors: Joseph SEEGER, Menlo Park, CA (US); Igor TCHERTKOV, San Jose, CA (US); Hasan AKYOL, Mountain View, CA (US); Goksen G. YARALIOGLU, Mountain View, CA (US); Steven S. NASIRI, Saratoga, CA (US); Ilya GURIN, Mountain View, CA (US)

(73) Assignee: INVENSENSE, INC., Sunnyvale, CA (US)

(21) Appl. No.: 13/536,798

(22) Filed: Jun. 28, 2012

Related U.S. Application Data
(60) Provisional application No. 61/502,616, filed on Jun. 29, 2011.
(60) Provisional application No. 61/502,603, filed on Jun. 29, 2011.

(51) Int. Cl. H01L 29/84; H01L 21/66; H01L 21/50

(52) U.S. Cl. 257/48; 257/415; 438/51; 438/15; 257/E29.324; 257/E21.499; 257/E21.521

(57) ABSTRACT

A system and method for providing a MEMS device with integrated electronics are disclosed. The MEMS device comprises an integrated circuit substrate and a MEMS subassembly coupled to the integrated circuit substrate. The integrated circuit substrate includes at least one circuit coupled to at least one fixed electrode. The MEMS subassembly includes at least one standoff formed by a lithographic process, a flexible plate with a top surface and a bottom surface, and a MEMS electrode coupled to the flexible plate and electrically coupled to the at least one standoff. A force acting on the flexible plate causes a change in a gap between the MEMS electrode and the at least one fixed electrode.

### CROSS-REFERENCE TO RELATED APPLICATION

This application claims the benefit of U.S. Provisional Patent Application No. 61/502,616, filed on Jun. 29, 2011, entitled “HERMETICALLY SEALED MEMS DEVICE WITH A PORTION EXPOSED TO THE ENVIRONMENT AND WITH VERTICALLY INTEGRATED ELECTRONICS,” which is incorporated herein by reference in its entirety. This application is related to U.S. Provisional Patent Application No. 61/502,603 filed Jun. 29, 2011, docket # IVS-154PR (5027PR), entitled “DEVICES AND PROCESSES FOR CMOS-MEMS INTEGRATED SENSORS WITH PORTION EXPOSED TO ENVIRONMENT,” and U.S. patent application Ser. No. ______, docket #IVS-154 (5027P), entitled “PROCESS FOR A SEALED MEMS DEVICE WITH A PORTION EXPOSED TO THE ENVIRONMENT,” filed concurrently herewith and assigned to the assignee of the present invention, all of which are incorporated herein in their entireties.

### FIELD OF THE INVENTION

The present invention relates to Microelectromechanical Systems (MEMS) devices, and more particularly, to MEMS devices that sense pressure.

### BACKGROUND

MEMS devices comprise a moveable microstructure that moves in response to forces such as inertial, electrostatic, magnetic or differential pressure. There is a strong need for a cost-effective solution that improves the detection of forces such as pressure. The present invention addresses such a need.

### SUMMARY OF THE INVENTION

A system and method for providing a MEMS device with integrated electronics are disclosed. In a first aspect, the MEMS device comprises an integrated circuit substrate and a MEMS subassembly coupled to the integrated circuit substrate. The integrated circuit substrate includes at least one circuit coupled to at least one fixed electrode. The MEMS subassembly includes at least one standoff formed by a lithographic process, a flexible plate with a top surface and a bottom surface, and a MEMS electrode coupled to the flexible plate and electrically coupled to the at least one standoff. A force acting on the flexible plate causes a change in a gap between the MEMS electrode and the at least one fixed electrode.

In a second aspect, the method comprises providing an integrated circuit substrate and coupling a MEMS subassembly to the integrated circuit substrate. The integrated circuit substrate includes at least one circuit coupled to at least one fixed electrode. The MEMS subassembly includes at least one standoff formed by a lithographic process, a flexible plate with a top surface and a bottom surface, and a MEMS electrode coupled to the flexible plate and electrically coupled to the at least one standoff. A force acting on the flexible plate causes a change in a gap between the MEMS electrode and the at least one fixed electrode.

### BRIEF DESCRIPTION OF THE DRAWINGS

The accompanying figures illustrate several embodiments of the invention and, together with the description, serve to explain the principles of the invention. One of ordinary skill in the art will recognize that the particular embodiments illustrated in the figures are merely exemplary, and are not intended to limit the scope of the present invention.

FIG. 1 illustrates a cross-section view of a MEMS device in accordance with a first embodiment.

FIG. 2 illustrates a cross-section view of a MEMS device in accordance with a second embodiment.

FIG. 3 illustrates a cross-section view of a MEMS device in accordance with a third embodiment.

FIG. 4 illustrates a cross-section view of a MEMS device in accordance with a fourth embodiment.

FIG. 5 illustrates a cross-section view of a MEMS device in accordance with a fifth embodiment.

FIG. 6 illustrates a cross-section view of a MEMS device in accordance with a sixth embodiment.

FIG. 7 illustrates a cross-section view of a MEMS device in accordance with a seventh embodiment.

FIG. 8 illustrates a cross-section view of a MEMS device in accordance with an eighth embodiment.

FIG. 9 illustrates operation of a MEMS device in accordance with a ninth embodiment.

FIG. 10 illustrates a graph displaying variation of flexible plate deflection as a function of ambient temperature.

FIG. 11 illustrates a cross-section view of a MEMS device in accordance with a tenth embodiment.

FIG. 12 illustrates operation of the MEMS device in accordance with the tenth embodiment.

FIG. 13 illustrates a cross-section view of the MEMS device with a dielectric in the sealed cavity in an embodiment.

FIG. 14 illustrates an embodiment of a cross-section view of the MEMS device with flexible plate decoupled from the handle substrate.

### DETAILED DESCRIPTION

The present invention relates to Microelectromechanical Systems (MEMS) devices, and more particularly, to MEMS devices that sense pressure. The following description is presented to enable one of ordinary skill in the art to make and use the invention and is provided in the context of a patent application and its requirements. Various modifications to the described embodiments and the generic principles and features described herein will be readily apparent to those skilled in the art. Thus, the present invention is not intended to be limited to the embodiments shown but is to be accorded the widest scope consistent with the principles and features described herein.

A system and method in accordance with the present invention provides force sensitive and force exerting MEMS devices with integrated electronics. By bonding an integrated circuit substrate that includes at least one fixed electrode to a MEMS subassembly that includes a lithographically formed standoff and a flexible plate with coupled MEMS electrode, a sealed cavity is formed with a reference pressure. Accordingly, a force acting on the flexible plate causes a deflection of the flexible plate and in turn, causes a change in a gap size formed by the sealed cavity between the MEMS electrode and the at least one fixed electrode.

The flexible plate of the MEMS devices deforms and deflects due to a variety of external forces acting on the portion of the flexible plate that is disposed externally and subject to the ambient surrounding environment. These external forces include but are not limited to pressure differences between the reference pressure and a pressure of the ambient surrounding environment, shear forces acting on the flexible plate, and other forces acting on the flexible plate via micro-flow and acceleration exertions.

Additionally, a system and method in accordance with the present invention describes a class of MEMS devices, sensors, and actuators including but not limited to pressure sensors, self-testing pressure sensors, accelerometers, force sensors, shear sensors, fluidic sensors, and micro-speakers that are hermetically sealed and bonded to integrated circuits, that use capacitive sensing and electrostatic actuation, and that have a flexible plate between the hermetically sealed cavity and the surrounding environment to allow the device to interact with the surrounding environment.

Features that enhance performance of the MEMS devices include but are not limited to electrode configurations for detecting and rejecting variations of gap between the MEMS electrode and the fixed electrode of the integrated circuit substrate, pressure sensor offset temperature dependence canceling techniques, pressure sensor self-testing and self-calibrating techniques, and pressure sensor particle filters that eliminate undesirable environmental factors.

To describe the features of the present invention in more detail, refer now to the following description in conjunction with the accompanying figures.

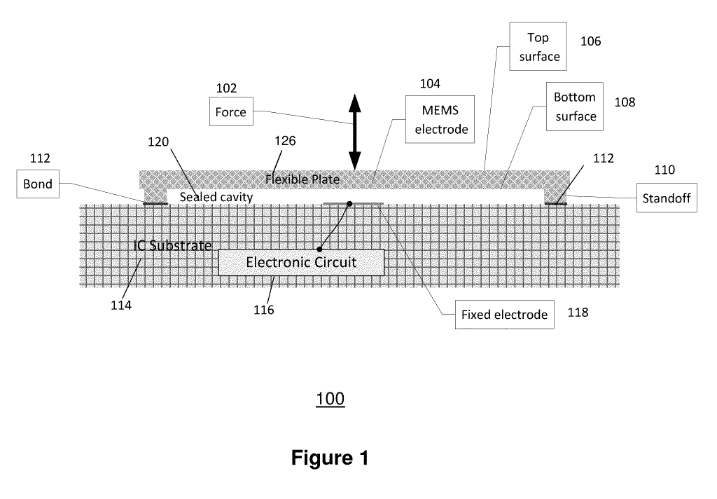

FIG. 1 illustrates a cross-section view of a MEMS device 100 in accordance with a first embodiment. The MEMS device 100 includes an integrated circuit substrate 114, an electronic circuit 116 coupled to the integrated circuit substrate 114, and a fixed electrode 118 coupled to the integrated circuit substrate 114. In one embodiment, the integrated circuit substrate 114 comprises CMOS circuitry. The MEMS device 100 also includes a MEMS subassembly that comprises a MEMS electrode 104, a flexible plate 126 coupled to the MEMS electrode 104, and at least one standoff 110 coupled to the MEMS electrode 104. The flexible plate 126 comprises a top surface 106 and a bottom surface 108. The MEMS subassembly is bonded to the integrated circuit substrate 114 via a bond 112 which forms a sealed cavity 120.

In FIG. 1, the sealed cavity 120 boundaries are defined by the integrated circuit substrate 114, the at least one standoff 110, and a portion of the bottom surface 108 of the flexible plate 126. In one embodiment, the sealed cavity 120 contains gas with a reference pressure (P_{ref}). The top surface 106 of the flexible plate 126 is exposed to an ambient environment including but not limited to the Earth's atmosphere with an ambient pressure (P_{amb}).

The gap between the MEMS electrode 104 and the fixed electrode 118 is determined by the at least one standoff 110 height. The combination of the MEMS electrode 104 and the fixed electrode 118 forms a capacitor. Deformation of the flexible plate 126 due to a force 102, including but not limited to pressure changes, causes changes in the gap between the MEMS electrode 104 and the fixed electrode 118. These changes in the gap in turn cause capacitance changes within the capacitor that are measured by a capacitive measurement process. In one embodiment, the capacitive measurement process includes connecting the capacitor to the integrated circuit substrate 114 with the embedded electronic circuit 116 then measuring a capacitance to indicate the amount of plate deformation resulting from the force 102.

In one embodiment, the flexible plate 126 is formed on a device layer such as a single crystal silicon device layer and is made from doped Silicon (Si) with a thickness range including but not limited to 1 micrometer (um) to 100 um. In this embodiment, the doped Si enables the flexible plate 126 to also serve as the MEMS electrode 104. The flexible plate 126 has at least one standoff 110 lithographically formed on its bottom surface 108. In this embodiment, the fixed electrode 118 is formed from a top metal layer of the CMOS integrated circuit substrate 114. One of ordinary skill in the art readily recognizes that the flexible plate 126 can be made to be responsive to various forces and that would be within the spirit and scope of the present invention.

The at least one standoff 110 is bonded to the integrated circuit substrate 114 by the bond 112 that is conductive to create an electrical connection between the integrated circuit substrate 114 and the MEMS electrode 104. One of ordinary skill in the art readily recognizes that the bond 112 can be a variety of different conductive bonds including but not limited to an aluminum-germanium eutectic bond and that would be within the spirit and scope of the present invention.

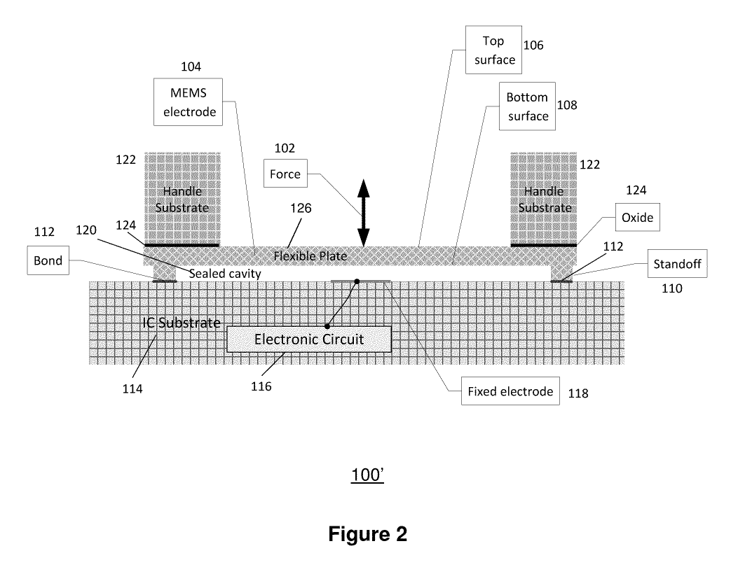

FIG. 2 illustrates a cross-section view of a MEMS device 100′ in accordance with a second embodiment. The MEMS device 100′ of FIG. 2 resembles the MEMS device 100 of FIG. 1, but also includes a handle substrate 122 coupled to the flexible plate 126 via an oxide 124 to form an opening that leaves the top surface 106 of the flexible plate 126 exposed to an ambient environment. In one embodiment, a micro-fluidic channel is formed by the opening created by the handle substrate 122. The flexible plate 126 forms the floor of the micro-fluidic channel. Viscous and other forces exerted by running fluid on the flexible plate 126 causes deformation of the flexible plate 126 which is in turn measured by the aforementioned capacitive measurement process.

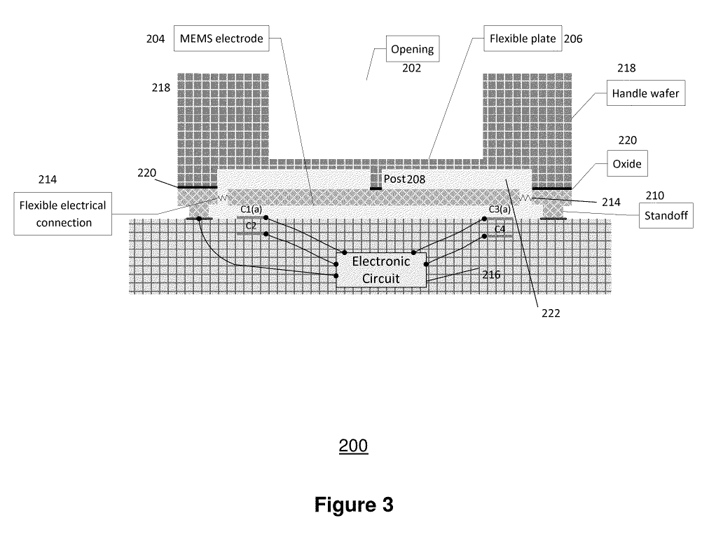

FIG. 3 illustrates a cross-section view of a MEMS device 200 in accordance with a third embodiment. The MEMS device 200 of FIG. 3 resembles the MEMS device 100′ of FIG. 2, but also includes a flexible electrical connection 214 that connects the at least one standoff 210 to the MEMS electrode 204 and a post 208 that connects the flexible plate 206 to the MEMS electrode 204. In an embodiment, electrode 204 may move in response due to pressure difference between the opening 202 and the sealed cavity 222. In another embodiment, electrode 204 may move in response due to the inertial forces acting on the electrode 204. Additionally, in FIG. 3, the electronic circuit 216 is connected to four electrodes to create the four capacitors C1(a), C3(a), C2, and C4 utilized for the pressure sensing or acceleration sensing.

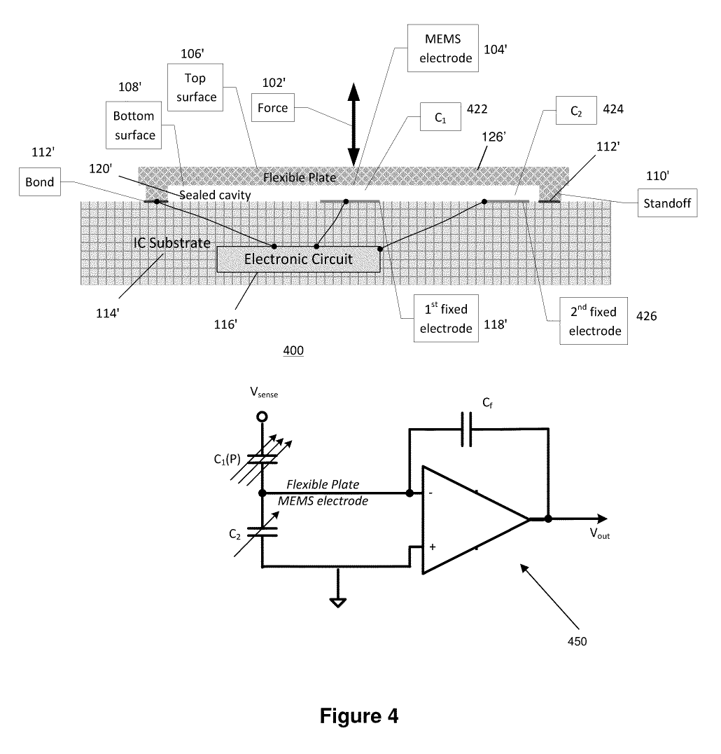

FIG. 4 illustrates a cross-section view of a MEMS device 400 in accordance with a fourth embodiment. The MEMS device 400 includes an integrated circuit substrate 114′, an electronic circuit 116′ coupled to the integrated circuit substrate 114′, and both a first fixed electrode 118′ and a second fixed electrode 426 coupled to the integrated circuit substrate 114′. The MEMS device 400 also includes a MEMS subassembly that comprises a MEMS electrode 104′, a flexible plate 126′ coupled to the MEMS electrode 104′, and at least one standoff 110′ coupled to the MEMS electrode 104′. In one embodiment, the flexible plate 126′ comprises a top surface 106′ and a bottom surface 108′. The MEMS subassembly is bonded to the integrated circuit substrate 114′ via a bond 112′ which forms a sealed cavity 120′.

The MEMS device 400 of FIG. 4 resembles the MEMS device 100 of FIG. 1 but has been configured to enable differential sensing. The first fixed electrode 118′ is disposed under a moving portion of the flexible plate 126′. The gap between the moving portion and the first fixed electrode 118′ is nominally defined by the height of the at least one standoff 110′, but changes due to pressure differences between the sealed cavity 120′ and the ambient surrounding environment. The second fixed electrode 426 is disposed under a reference portion of the flexible plate 126′ which is located substantially closer to the at least one standoff 110′. The gap between the second fixed electrode 426 and the reference portion of the flexible plate 126′ is also nominally defined by the height of the at least one standoff 110′, but is less sensitive to external pressure in comparison to the moving portion.

In FIG. 4, the first fixed electrode 118′ and the moving portion of the flexible plate 126′ form a first capacitor (C₁) 422 and the second fixed electrode 426 and the reference portion of the flexible plate 126′ form a second capacitor (C₂) 424. The electronic circuit 116′ measures a difference between the first and the second capacitors 422-424 in response to the force 102′ including but not limited to pressure changes. In one embodiment, the electronic circuit 116′ is insensitive to manufacturing variations of the height of the at least one standoff 110′. In this embodiment, the electronic circuit 116′, shown in the bottom part of FIG. 4, is designed using switched-capacitor techniques and is a half-bridge arrangement 450 that senses the difference between the two capacitors 422-424.

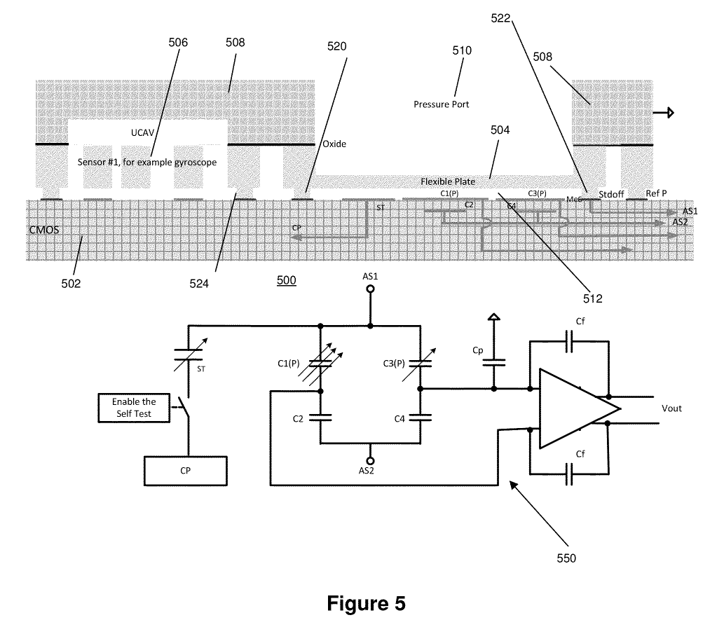

FIG. 5 illustrates a cross-section view of a MEMS device 500 in accordance with a fifth embodiment. The MEMS device 500 includes a CMOS integrated circuit substrate 502, a flexible plate 504 coupled to the CMOS substrate 502, a second MEMS device 506 coupled to the CMOS substrate 502, a handle substrate 508 coupled to the flexible plate 504, and a pressure port 510 located above the flexible plate 504. A portion of the handle substrate 508 is opened to form the pressure port 510 and expose the flexible plate 504 to the environment. The second MEMS device 506 is formed in the device layer and horizontally integrated with the pressure port 510. The second MEMS device 506 is covered by the handle substrate 508 and flexible plate 504. Handle substrate 508 may be connected ground potential through wire bond or through-silicon via (TSV) or other similar techniques. One of ordinary skill in the art readily recognizes that the second MEMS device 506 can be a variety of devices including but not limited to a gyroscope or accelerometer and that would be within the spirit and scope of the present invention.

In an embodiment, sealed cavity 512 may be formed by the flexible plate 504, standoffs 520 and 522 and CMOS substrate 502 and sealed at a certain pressure. A second sealed cavity enclosing second MEMS device 506 may be separately sealed at a different pressure than the sealed cavity 512. In an embodiment, the sealed cavity 512 and the second sealed cavity may be sealed at the same pressure by opening a portion of the standoffs. In an embodiment, sealed cavity 512 is bounded by the standoffs 520 and 522. In another embodiment, a portion of standoff 520 is opened (not shown in FIG. 5) such that sealed cavity is bound by standoffs 522 and 524. In another embodiment, a portion of standoff 520 and 524 are opened to extend sealed cavity 512 to include the second sealed cavity.

The MEMS device 500 of FIG. 5 resembles the MEMS device 400 of FIG. 4 but also includes two additional capacitors C2 and C4 formed in the CMOS integrated circuit substrate 502. In one embodiment, the two additional capacitors C2 and C4 are formed by two metal layers used in a CMOS process. In another embodiment, capacitor C2 is disposed right below capacitor C1(P) and capacitor C4 is disposed right below capacitor C3(P). In this embodiment, all four capacitors C1(P), C2, C3(P), and C4 are designed to be equal at a particular value of P_{amb}. One of ordinary skill in the art readily recognizes that the four capacitors can be arranged in a variety of different configurations and that would be within the spirit and scope of the present invention.

The electronic circuit, embedded within the CMOS integrated circuit substrate 502 and shown in the bottom part of FIG. 5, is designed to electrically connect these four capacitors C1(P), C2, C3(P), and C4 to form a capacitive bridge circuit 550. Driving potentials are applied to terminals of the capacitive bridge circuit 550 labeled AS1-ACT and AS2-Me5. Bridge output terminals are labeled Me6-PM2 and Me6-PM1. The capacitive bridge circuit 550 outputs a signal that is proportional to the capacitance difference according to the following equation: C1(P)−C2−C3(P)+C4. As a result, the output of the capacitive bridge circuit 550 changes due to pressure differences across the flexible plate 504. In another embodiment, the electronic circuit is designed and implemented as a switched-capacitor circuit.

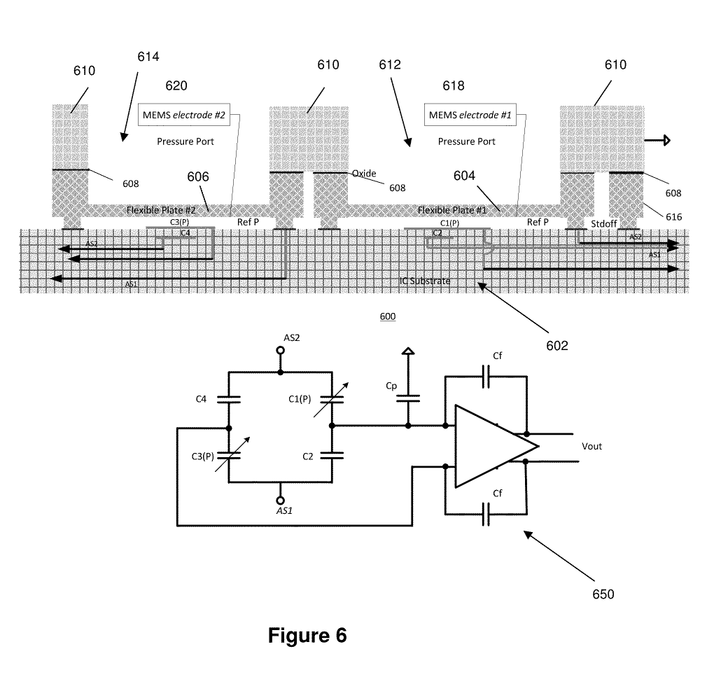

FIG. 6 illustrates a cross-section view of a MEMS device 600 in accordance with a sixth embodiment. The MEMS device 600 includes an integrated circuit substrate 602 coupled to both a first flexible plate 604 and a second flexible plate 606, a first MEMS electrode 618 coupled to the first flexible plate 604, a second MEMS electrode 620 coupled to the second flexible plate 606, a handle substrate 610 coupled to both the first and second flexible plates 604-606 via an oxide layer 608 and at least one standoff 616, a first pressure port 612 formed by an opening in the handle substrate and located above the first flexible plate 604, and a second pressure port 614 located above the second flexible plate 606.

The electronic circuit, embedded within the integrated circuit substrate 602 and shown in the bottom part of FIG. 6, is designed using switched-capacitor techniques as two identical half-bridge arrangements 650 disposed side by side. As a result, in this electronic circuit, all four capacitors C1(P), C2, C3(P), and C4 are configured in a full bridge circuit.

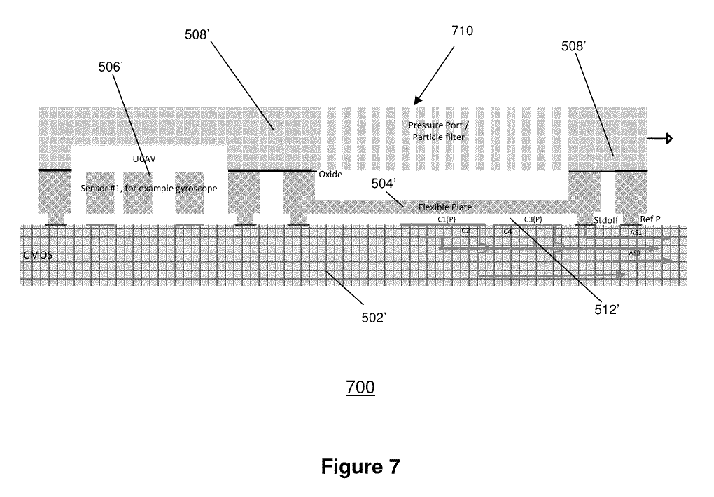

FIG. 7 illustrates a cross-section view of a MEMS device 700 in accordance with a seventh embodiment. The MEMS device 700 of FIG. 7 resembles the MEMS device 500 of FIG. 5, but includes a particle filter 710 formed in the handle substrate to enhance environmental protection of the MEMS device 700. The particle filter 710 helps eliminated undesirable environmental factors from disturbing the operation and functionality of the MEMS device 700. In one embodiment, the particle filter 710 is formed by etching long and narrow channels with varying cross-sections including but not limited to approximately 2 μm×2 μm.

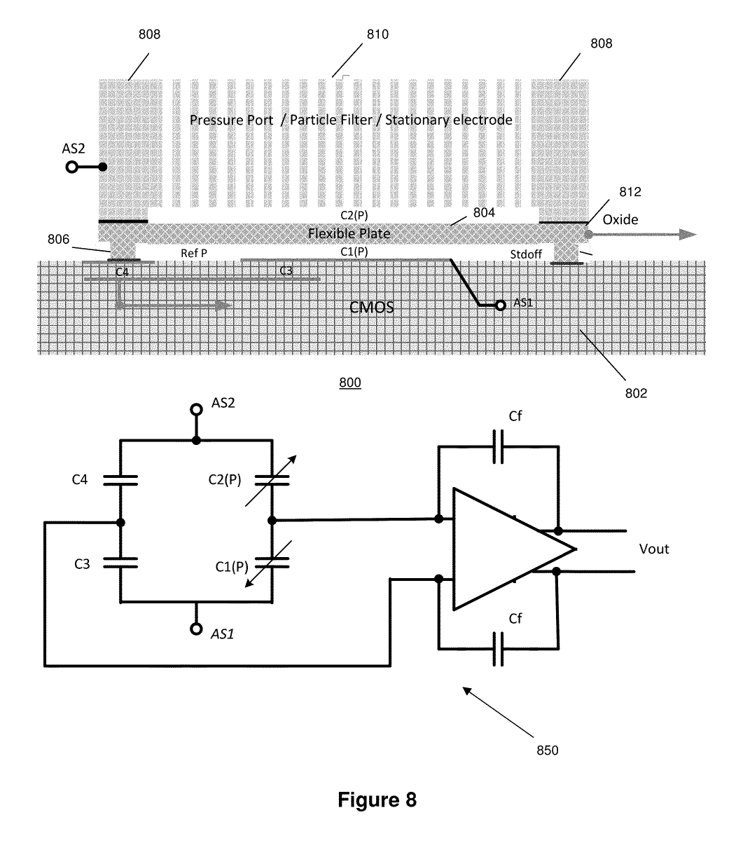

FIG. 8 illustrates a cross-section view of a MEMS device 800 in accordance with an eighth embodiment. FIG. 8 includes an electronic circuit diagram 850 describing the circuitry configuration of the MEMS device 800. The MEMS device 800 includes a CMOS substrate 802, a flexible plate 804 coupled to the CMOS substrate 802 via at least one standoff 806 forming a sealed cavity, a handle substrate 808 coupled to the flexible plate 804 via an oxide layer 812, and a particle filter 810 formed in the handle substrate 808 located above the flexible plate 804.

In one embodiment, particle filter 810 is used as a stationary electrode. In FIG. 8, the particle filter 810 is connected to a driving node of the CMOS substrate 802 forming two capacitors C1(P) and C2(P) that are responsive to pressure difference variations by using the particle filter 810 as a second fixed electrode disposed above a top surface of the flexible plate 804. The two variable capacitors C1(P) and C2(P) respond to pressure difference variations in exact opposite ways. As a result, if one of the capacitors increases its value, the other capacitor decreases its value which affords full differential pressure sensing that includes increased (doubled) sensitivity.

In one embodiment, channels of the particle filter 810 are partially filled with a soft protective gel or oil that are kept in place by an adhesive or surface tension forces. The soft protective gel or oil acts as an impermeable barrier against particles and moisture while still transmitting pressure difference variations without any significant attenuation. One of ordinary skill in the art readily recognizes that the channels of the particle filter 810 may be partially filled at varying levels and by a variety of materials and that would be within the spirit and scope of the present invention.

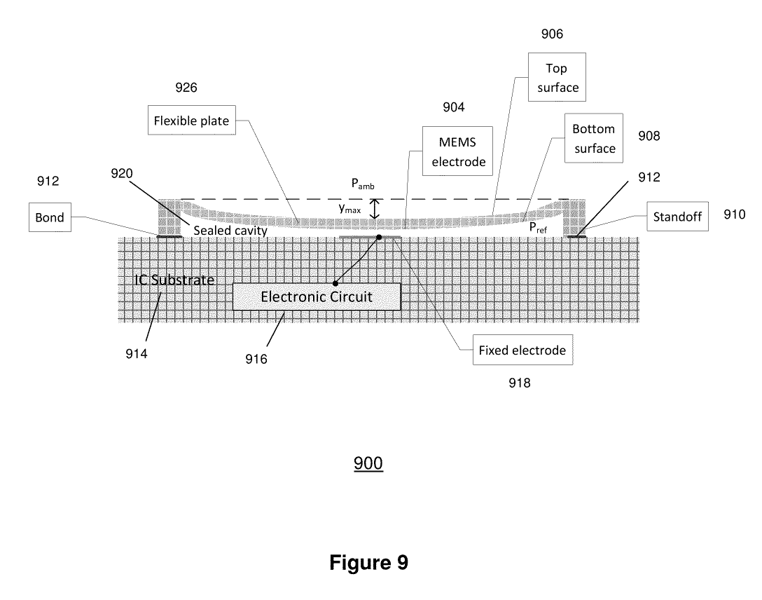

FIG. 9 illustrates operation of a MEMS device 900 in accordance with a ninth embodiment. The MEMS device 900 includes an integrated circuit substrate 914, an electronic circuit 916 coupled to the integrated circuit substrate 914, and a fixed electrode 918 coupled to the integrated circuit substrate 914. The MEMS device 900 also includes a MEMS subassembly that comprises a MEMS electrode 904, a flexible plate 926 coupled to the MEMS electrode 904, and at least one standoff 910 coupled to the MEMS electrode 904. The flexible plate 926 comprises a top surface 906 and a bottom surface 908. The MEMS subassembly is bonded to the integrated circuit substrate 914 via a bond 912 which forms a sealed cavity 920.

The flexible plate 926 is deformed due to an ambient environment pressure (P_{amb}) being greater than a reference pressure (P_{ref}) or a P_{amb}>P_{ref} condition. These two pressures are separated by the flexible plate 926. In one embodiment, the flexible plate 926 is thin. One of ordinary skill in the art readily recognizes that the thinness of the flexible plate 926 can be of varying degrees and that would be within the spirit and scope of the present invention.

The sealed cavity 920 disposed on one side of the flexible plate 926 is sealed during factory manufacturing at a reference pressure of P_{ref} including but not limited to 0.1 to 100 millibar (mbar) or 10.1 Pascal (Pa) to 10.1 kPa. The other side of the flexible plate 926 is exposed to an ambient environment pressure of P_{amb}. In one embodiment, P_{amb} is atmospheric pressure which at sea level is approximately 1 atm or 101 ·kPa. One of ordinary skill in the art readily recognizes that P_{amb} changes as a result of meteorological conditions and as a function of elevation and these changes would be within the spirit and scope of the present invention.

The flexible plate 926 deforms due to a pressure difference P_{amb}−P_{ref} and a maximal deflection point of the flexible plate 926 is described by the following equation, where k_{eff} is an effective stiffness of the flexible plate 926:

$${y}_{max} = \frac{1}{{k}_{eff}} ( {P}_{amb} - {P}_{ref} ) . \qquad ( 1 )$$

In one embodiment, the effective stiffness of a square membrane with fixed edges, thickness of h, and side length of b is described by the following equation, where E is the Young's modulus:

$${k}_{eff} = \frac{E {h}^{5}}{( .0138 ) {b}^{4}} . \qquad ( 2 )$$

The flexible plate 926 deflection also changes due to a temperature variation of the structural material stiffness of the flexible plate 926 and due to a temperature variation of the reference pressure. In one embodiment, there is a vacuum in the sealed cavity 920 and so the reference pressure P_{ref} is 0. In this embodiment, the deflection of the flexible plate 926 is influenced only by a temperature variation of the structural material stiffness of the flexible plate 926. One of ordinary skill in the art readily recognizes that most materials become softer with temperature rises and so the deflection of the flexible plate 926 will increase with temperature and that would be within the spirit and scope of the present invention.

In another embodiment, the flexible plate 926 is made from a very soft material, moves essentially as a piston, and the sealed cavity 920 is sealed while containing gas at a reference pressure P_{ref}. In this embodiment, when temperature rises, the pressure exerted by the gas on the flexible plate 926 rises as well which pushes the flexible plate 926 away from the integrated circuit substrate 914. This results in a reduction in the deflection of the flexible plate 926.

In another embodiment, the sealed cavity 920 is sealed while containing gas at a particular pressure that results in the deflection of the flexible plate 926 being insensitive to temperature variation due to a canceling of two effects. The first effect of a temperature variation of the deflection of the flexible plate 926 is described by the following equation:

$$\frac{d {y}_{max}}{d T} = \frac{1}{{k}_{eff}} ( - \frac{d {k}_{eff}}{d T} \frac{1}{{k}_{eff}} ( {P}_{amb} - {P}_{ref} ) - \frac{d {P}_{ref}}{d T} ) . \qquad ( 3 )$$

According to the ideal gas law, the second effect of a pressure in the sealed cavity 920 is proportional to an absolute temperature and is described by the following equation:

$$\frac{d {P}_{ref}}{d T} = \frac{{P}_{ref}}{T} . \qquad ( 4 )$$

At a specific reference pressure, these two effects cancel each other out resulting in a deflection of the flexible plate 926 that is temperature independent. This specific reference pressure is described by the following equation:

$${P}_{ref} = {P}_{amb} \frac{- \frac{d E}{d T} \frac{T}{E}}{( 1 - \frac{d E}{d T} \frac{T}{E} )} . \qquad ( 5 )$$

In one embodiment that uses a silicon material, the typical variation of Young's modulus is −40 ppm/K. In this embodiment, at a temperature of T=300 Kelvin (K), the reference pressure P_{ref} that provides a cancellation of these two effects is approximately described by the following equation:

P_{ref}=0.0118*P_{amb} (6).

As a result, a MEMS device utilizing equation (6) to cancel the two aforementioned effects does not require independent temperature measurement by an on-board temperature sensor. One of ordinary skill in the art readily recognizes that a variety of temperatures and varying materials will result in changes to these aforementioned equations and that would be within the spirit and scope of the present invention.

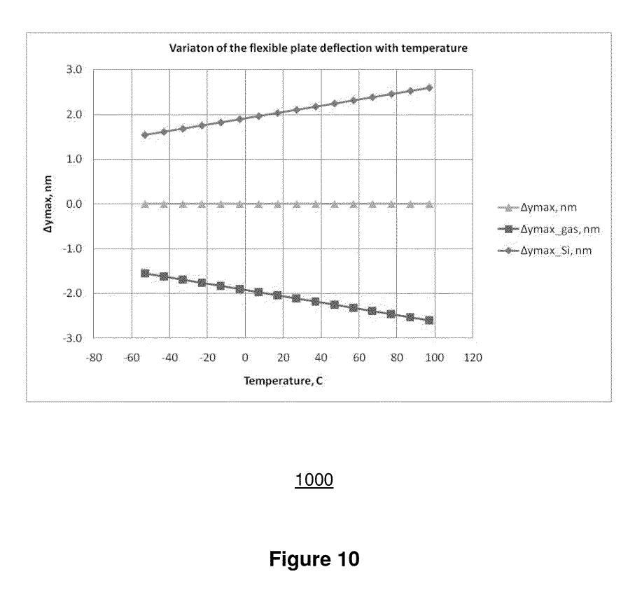

FIG. 10 illustrates a graph 1000 displaying variation of flexible plate defection as a function of ambient temperature. The graph 1000 is computed using aforementioned equation (3). In the graph 1000, Δymax_Si plots contribution from a Si Young modulus only, Δymax_gas plots contribution only from gas in the sealed cavity, and Δymax plots variation of the flexible plate deflection in a perfectly compensated pressure sensor prescribed by aforementioned equation (6).

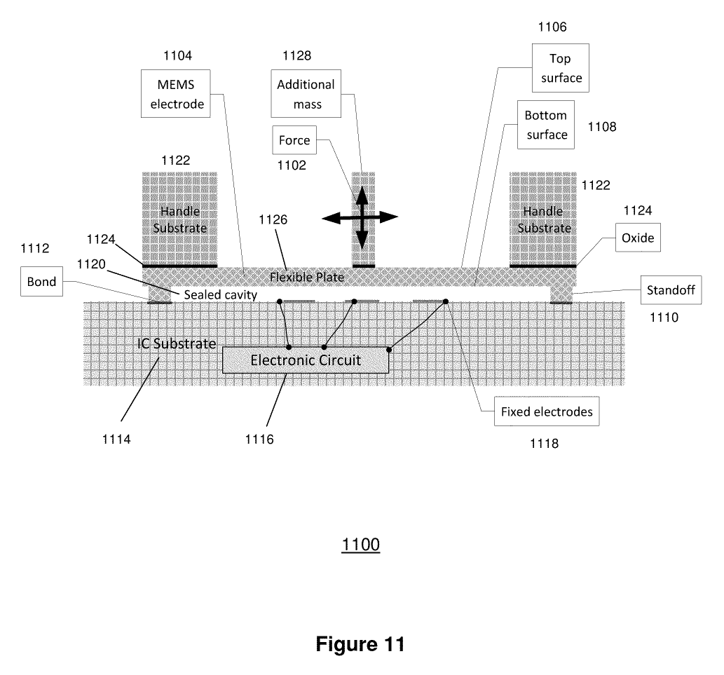

FIG. 11 illustrates a cross-section view of a MEMS device 1100 in accordance with a tenth embodiment. The MEMS device 1100 includes an integrated circuit substrate 1114, an electronic circuit 1116 coupled to the integrated circuit substrate 1114, and at least one fixed electrode 1118 coupled to the integrated circuit substrate 1114. The MEMS device 1100 also includes a MEMS subassembly that comprises a MEMS electrode 1104, a flexible plate 1126 coupled to the MEMS electrode 1104, and at least one standoff 1110 coupled to the MEMS electrode 1104.

The flexible plate 1126 comprises a top surface 1106 and a bottom surface 1108. The MEMS subassembly is bonded to the integrated circuit substrate 1114 via a bond 1112 which forms a sealed cavity 1120. A handle substrate 1122 is bonded to the flexible plate 1126 via an oxide layer 1124. An additional mass 1128 is also coupled to the top surface 1106 of the flexible plate 1126 to enable sensing of additional forces. In one embodiment, these additional forces include but are not limited to accelerations parallel and normal to the flexible plate 1126 and shear forces. In another embodiment, the additional mass 1128 is coupled to a joystick to enable tracking of joystick motion.

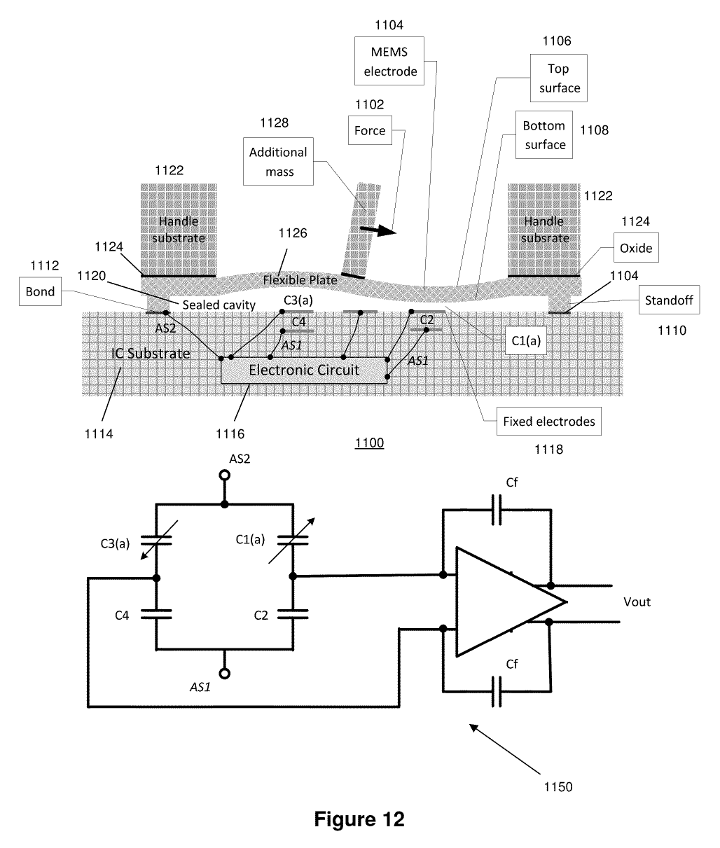

FIG. 12 illustrates operation of the MEMS device 1100 in accordance with the tenth embodiment. FIG. 12 includes an electronic circuit diagram 1150 describing the circuitry configuration of the MEMS device 1100. FIG. 12 shows motion of the additional mass 1128 in a first direction parallel to the integrated circuit substrate 1114. The flexible plate 1126 is deformed due to an application of shearing forces.

In one embodiment, three fixed electrodes are disposed under the flexible plate 1126: a first fixed electrode disposed under a middle portion of the flexible plate 1126, a second fixed electrode disposed to the left of the first fixed electrode, and a third fixed electrode disposed symmetrically to the right of the first fixed electrode. In this embodiment, shear forces cause capacitance of the second fixed electrode and the third fixed electrode to change oppositely, i.e. when the capacitance of the second fixed electrode increases the capacitance of the third fixed electrode decreases. In this embodiment, normal forces cause all capacitance to change (i.e. increase or decrease) similarly. In another embodiment, four fixed electrodes are disposed under the flexible plate 1126 on the CMOS substrate to measure motion normal to the substrate and motion in a first direction parallel to the substrate and motion in a second direction parallel to the substrate and orthogonal to the first direction.

Electrostatic actuation of the aforementioned MEMS devices is enabled by forming at least one more electrode on the integrated circuit substrate. This self-testing feature can also be used for self-calibration of the device at the factory, which lowers the cost of testing by eliminating the need for external pressure chambers. Electrostatic actuation of the flexible plate can be used for self-testing and self-calibration of the MEMS device and can be used to create a variety of devices including but not limited to micro-speakers, micro-mirrors, and MEMS devices that modulate light.

Referring back to FIG. 5, the at least one more electrode is labeled ST for self-testing and is coupled to the CMOS substrate 502. In one embodiment, a voltage of 25V is applied to the at least one more ST electrode during self-testing. One of ordinary skill in the art readily recognizes that this voltage can be generated by a variety of methodologies including but not limited to a charge pump (CP) coupled to the CMOS substrate 502 in FIG. 5 and that would be within the spirit and scope of the present invention. During this self-testing, an attractive electrostatic force is developed and applied to the flexible plate causing the flexible plate to deflect toward the fixed electrode in a similar fashion as an additional external pressure would.

The resulting function and emulated pressure is used for the self-testing of the pressure sensor MEMS device and is described by the following equation, where Pₛₜ is a self-testing pressure, F_{S}, is a self-testing force, A_{memb} is an area of the flexible plate, Aₛₜ is an area of the self-testing electrode ST, ∈ is dielectric permittivity (e.g. 8.85e-12F/m for vacuum); Vₛₜ is self-testing potential, g is gap between the bottom of the reference sealed cavity/chamber and flexible plate, and k is a coefficient taking into account that the flexible plate bends as opposed to moving in a piston-like motion:

$${P}_{ST} = \frac{{F}_{ST}}{{A}_{memb}} = \frac{k \cdot \frac{ɛ \cdot {A}_{ST} {V}_{ST}^{2}}{{g}^{2}}}{{A}_{memb}} = \frac{k ɛ \cdot {A}_{ST} {V}_{ST}^{2}}{{A}_{memb} \cdot {g}^{2}} . \qquad ( 7 )$$

The aforementioned MEMS devices are utilized for a variety of applications including but not limited to pressure sensor devices, shear force sensor devices, and force exerting devices. As force exerting devices, the MEMS devices operate as micro-speakers, micro-mirrors, and micro-light modulating devices.

Additionally, disposing part of the flexible plate of these MEMS devices to the environment enables these MEMS devices to sense and actuate more than just pressure changes and variations. The MEMS devices described by FIG. 3, FIG. 11, and FIG. 12 include signal processing schematics that are arranged to enable the MEMS device to function as an accelerometer. These schematics illustrate how a full capacitive Wheatstone bridge is formed to afford differential sensing and common mode rejections.

In another embodiment, the top surface of the flexible plate(s) of these aforementioned MEMS devices is coated with a chemical compound that is capable of absorbing selective gas or fluid species from the environment. Based upon deformations of the flexible plate resulting from these absorptions, the chemical compound coating enables the MEMS device for micro-balanced chemical sensing.

In one embodiment, the capacitive gap determined by the standoffs of the aforementioned MEMS devices is subject to manufacturing tolerances and variability that ordinarily lead to capacitance variations and therefore variability in sensor outputs. To combat this variability, in one embodiment, the aforementioned MEMS devices utilize common gap values for both capacitors C1(P) and C3(P) by the implemented differential sensing.

One of the merits of any force sensing MEMS device is the ability to resolve very small variations in forces which result in very small yₘₐₓ variation sensing capabilities on the level of picometers (˜10⁻¹² m) and in very small C1(P) sensing on the level of a atto-Farads (˜10⁻¹⁸ F). These small electrical signals are difficult to measure and are easily overwhelmed by various environmental factors. To combat these various environmental factors, in one embodiment, the aforementioned MEMS device utilize sensing nodes of the capacitive bridge formed by the first and second fixed electrodes which are electrically shielded from the environment by the conductive flexible plate and by the third and fourth fixed electrodes. The third and fourth fixed electrodes are the driven nodes of the capacitive bridge and carrying higher potentials than the first and second fixed electrodes. This results in the third and fourth fixed electrodes being less susceptible to these various environmental factors.

As above described, the system and method allow for more efficient and more accurate force sensing and force exerting MEMS devices that are capable of self-testing and self-calibrating. By coupling an integrated circuit substrate with a fixed electrode to a MEMS subassembly that includes a MEMS electrode coupled to a flexible plate, a hermetically sealed cavity/chamber is formed between the fixed electrode and the MEMS electrode that enables the sensing of various forces by a force responsive capacitive pressure sensor device. Thus, on one side of the flexible plate of this force responsive capacitive pressure sensor device is the hermetically sealed cavity/chamber and the other side is exposed to the surrounding ambient environment.

The at least one standoff formed on the MEMS subassembly determines the gap size of the hermetically sealed cavity/chamber and forms an electrical connection to the integrated circuit substrate. This capacitive pressure sensor can be integrated with other MEMS devices including but not limited to force-responsive devices on the same MEMS subassembly. This capacitive pressure sensor can also be integrated with other CMOS-based sensors including but not limited to temperature, light, and proximity sensors.

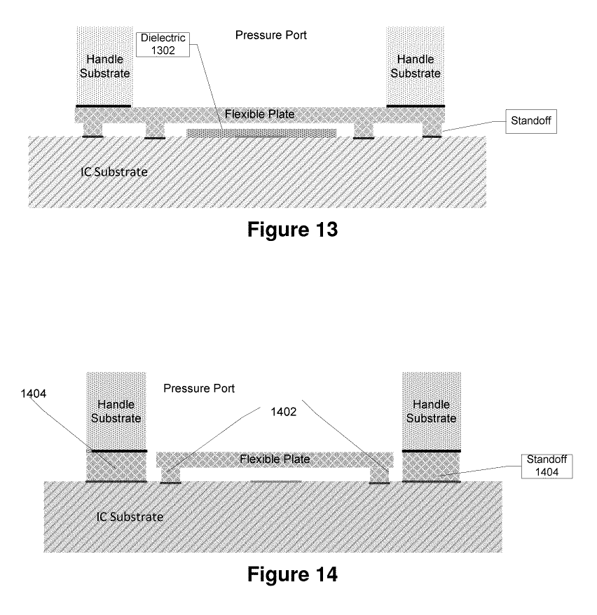

FIG. 13 illustrates an embodiment of a cross-section view of a MEMS device with a dielectric in the sealed cavity. In an embodiment, dielectric 1302 may disposed over the fixed electrode, with thickness less than the height of the standoffs. The dielectric can be formed from, for instance, the passivation layer of the IC substrate. The dielectric functions as an over-travel stop, preventing the flexible plate from impacting the fixed electrode. In another embodiment, dielectric 1302 may disposed next to the fixed electrode without covering the fixed electrode. Dielectric 1302 enhances the electrostatic fields in the gap when the fixed electrode is disposed over the fixed electrode.

FIG. 14 illustrates an embodiment of a cross-section view of a MEMS device with the flexible plate decoupled from the handle substrate. In an embodiment, the standoffs 1402 are uncoupled to the handle substrate and underneath the pressure port. Standoffs 1404 may provide hermitic seal for other MEMS devices (not shown in FIG. 14). A portion of the IC substrate exposed by the pressure port may require a passivation layer.

Although the present invention has been described in accordance with the embodiments shown, one of ordinary skill in the art will readily recognize that there could be variations to the embodiments and those variations would be within the spirit and scope of the present invention. Accordingly, many modifications may be made by one of ordinary skill in the art without departing from the spirit and scope of the appended claims.

What is claimed is:

1. A Microelectromechanical Systems (MEMS) device with integrated electronics,
the MEMS device comprising:
an integrated circuit substrate, wherein the integrated circuit substrate includes at least one circuit coupled to at least one fixed electrode; and
a MEMS subassembly coupled to the integrated circuit substrate,
wherein the MEMS subassembly includes at least one standoff formed by a lithographic process, a flexible plate with a top surface and a bottom surface,
and a MEMS electrode coupled to the flexible plate and electrically coupled to the at least one standoff,
wherein a force acting on the flexible plate causes a change in a gap between the MEMS electrode and the at least one fixed electrode.

2. The MEMS device of claim 1, wherein the at least one standoff defines the gap between the MEMS electrode and the at least one fixed electrode, wherein the at least one standoff is bonded with a conductive bond to the integrated circuit substrate to form a sealed cavity and to form an electrical connection between the MEMS electrode and the integrated circuit substrate.

3. The MEMS device of claim 2, wherein at least one portion of the bottom surface of the flexible plate is a surface of the sealed cavity and at least one portion of the top surface of the flexible plate is exposed to an ambient environment.

4. The MEMS device of claim 3, wherein the MEMS subassembly further includes:
a device layer bonded to a handle substrate, wherein the at least one standoff and the flexible plate are formed on the device layer, wherein an opening in the handle substrate exposes the at least one portion of the top surface of the flexible plate to the ambient environment.

5. The MEMS device of claim 2, wherein the force results from a difference between ambient pressure and pressure in the sealed cavity.

6. The MEMS device of claim 5, wherein the pressure in the sealed cavity is chosen such that temperature dependence of a pressure sensor offset is cancelled.

7. The MEMS device of claim 1, wherein the at least one fixed electrode is a first and a second fixed electrode disposed on the integrated circuit substrate, wherein the first fixed electrode is near a moving portion of the MEMS electrode and the second fixed electrode is near a reference portion of the MEMS electrode, wherein the reference portion responds to force differently than the moving portion.

8. The MEMS device of claim 7, further comprising:
a first capacitor formed between the first fixed electrode and the moving portion; and
a second capacitor formed between the second fixed electrode and the reference portion, wherein a capacitance difference is measured between the first and the second capacitors to sense force and reject gap variation.

9. The MEMS device of claim 7, further comprising:
a third and a fourth capacitor formed on the integrated circuit substrate, wherein the third capacitor is coupled to the first fixed electrode and the fourth capacitor is coupled to the second fixed electrode, wherein the first, the second, the third, and the fourth capacitors are arranged to form a capacitive bridge configuration.

10. The MEMS device of claim 7, wherein the at least one fixed electrode is at least one self-test electrode, wherein an electrostatic force is created by applying an electric potential difference between the at least one self-test electrode and the MEMS electrode, whereby the electrostatic force acts on the flexible plate to cause a deflection of the flexible plate.

11. The MEMS device of claim 10, wherein the electrostatic force is substantially parallel to the flexible plate causing tilt of the flexible plate measured by the first and the second electrodes.

12. The MEMS device of claim 1, further comprising:
an additional mass coupled to the flexible plate and at least three fixed electrodes to measure motion normal to the integrated circuit substrate and motion in a first direction parallel to the integrated circuit substrate and motion in a second direction parallel to the integrated circuit substrate and orthogonal to the first direction.

13. The MEMS device of claim 1, further comprising:
a flow channel coupled to the top surface of the flexible plate, wherein force acting on the flexible plate is of fluid-structure interaction nature.

14. The MEMS device of claim 4, wherein the handle substrate includes a particle filter.

15. The MEMS device of claim 1, further comprising:
a second flexible plate with a top surface and a bottom surface, wherein at least one portion of the bottom surface of the a second flexible plate is a surface of a second sealed cavity and at least one portion of the top surface of the second flexible plate is exposed to the ambient environment, wherein at least one portion of the second flexible plate serves as a reference electrode and is coupled to at least another standoff; and
a second MEMS electrode coupled to the second flexible plate, wherein the second MEMS electrode is electrically coupled to the at least another standoff, wherein the second MEMS electrode is near a second fixed electrode disposed on the integrated circuit substrate.

16. The MEMS device of claim 1, further comprising:
a chemical compound coating coupled to the top surface of the flexible plate, wherein the chemical compound coating enables micro-balanced chemical sensing.

17. The MEMS device of claim 1, further comprising:
a self-testing electrode coupled to the integrated circuit substrate; and
a charge pump coupled to the integrated circuit substrate, wherein the charge pump is activated to self-test and self-calibrate the MEMS device.

18. A method for providing a Microelectromechanical Systems (MEMS) device with integrated electronics, the method comprising:
providing an integrated circuit substrate, wherein the integrated circuit substrate includes at least one circuit coupled to at least one fixed electrode; and
coupling a MEMS subassembly to the integrated circuit substrate, wherein the MEMS subassembly includes at least one standoff formed by a lithographic process, a flexible plate with a top surface and a bottom surface, and a MEMS electrode coupled to the flexible plate and electrically coupled to the at least one standoff, wherein a force acting on the flexible plate causes a change in a gap between the MEMS electrode and the at least one fixed electrode.

19. The method of claim 18, further comprising:
applying an electric potential difference between at least one self-test electrode of an integrated circuit substrate and a MEMS electrode coupled to the flexible plate to create an electrostatic force, whereby the electrostatic force acts on the flexible plate causing the deflection to self-test and self-calibrate the MEMS device.

20. The method of claim 18, further comprising:
coupling a particle filter to the flexible plate, wherein the particle filter enhances environmental protection of the MEMS device.
